(19) United States
(12) Patent Application Publication
(10) Pub. No.: US 2013/0228926 A1
(43) Pub. Date: Sep. 5, 2013

(54) INTERCONNECTION STRUCTURE

(71) Applicants: Takeaki Maeda, Kobe-shi (JP); Toshihiro Kugimiya, Kobe-shi (JP)

(72) Inventors: Takeaki Maeda, Kobe-shi (JP); Toshihiro Kugimiya, Kobe-shi (JP)

(73) Assignee: KABUSHIKI KAISHA KOBE SEIKO SHO (KOBE STEEL, LTD.), Kobe-shi, Hyogo (JP)

(21) Appl. No.: 13/882,635

(22) PCT Filed: Oct. 11, 2011
(86) PCT No.: PCT/JP2011/073354

§ 371 Date: Apr. 30, 2013

(30) Foreign Application Priority Data
Nov. 12, 2010 (JP) 2010-254180

(51) Int. Cl. H01L 23/532

(52) U.S. Cl. CPC H01L 23/53238
USPC 257/751

(57) ABSTRACT

Provided is an interconnection structure that, in a display device such as an organic EL display or a liquid crystal display, has superior workability during wet etching even without providing an etch stop layer. The interconnection structure has, in the given order, a substrate, a semiconductor layer of a thin film transistor, and a metal interconnection film, and has a barrier layer between the semiconductor layer and the metal interconnection film. The semiconductor layer comprises an oxide semiconductor, the barrier layer has a layered structure of a high-melting-point metal thin film and a Si thin film, and the Si thin film is directly connected to the semiconductor layer.

### TECHNICAL FIELD

The present invention relates to a technology useful for an interconnection structure having an oxide semiconductor layer as a semiconductor layer, the interconnection structure being used for a flat panel display such as a liquid crystal display and an organic EL display.

### BACKGROUND ART

An aluminum (Al) alloy film, which has excellent workability and relatively low electric resistance, is generally used as an interconnection material for a display typically including a liquid crystal display. Copper (Cu) having lower resistance than that of Al is now the subject of interest as an interconnection material useful for a display having a larger size and higher image quality. While Al has a resistivity of 2.5×10⁻⁶ Ω·cm, Cu has a resistivity as low as 1.6×10⁻⁶ Ω·cm.

In addition, oxide semiconductor is now the subject of interest as a material for a semiconductor layer used in a display. The oxide semiconductor has wide carrier mobility and large optical bandgap compared with generally used amorphous silicon (a-Si), and can be deposited at low temperature. It is therefore promised to use the oxide semiconductor for a next-generation display, to which large size, high resolution, and fast driving frequency are required, and for a resin substrate having low heat resistance.

The oxide semiconductor contains at least one element selected from a group consisting of In, Ga, Zn, and Sn, examples of which typically include In-contained oxide semiconductor such as In—Ga—Zn—O, In—Zn—Sn—O, and In—Zn—O. In addition, Zn-contained oxide semiconductor such as Zn—Sn—O and Ga—Zn—Sn—O has also been proposed as oxide semiconductor suitable for mass production since it contains no In being a rare metal, and achieves a reduction in material cost (for example, see PTL1).

### CITATION LIST

### Patent Literature

PTL1: Japanese Unexamined Patent Application Publication No. 2004-163901.

### SUMMARY OF THE INVENTION

### Problems that the Invention is to Solve

However, for example, if oxide semiconductor is used as a semiconductor layer of a bottom-gate TFT, and if a Cu film is used as an interconnection material for a source or drain electrode directly connected to that oxide semiconductor, Cu disadvantageously diffuses into the oxide semiconductor layer, resulting in degradation in TFT characteristics. It is therefore necessary to provide a barrier metal between the oxide semiconductor layer and the Cu film in order to prevent diffusion of Cu into the oxide semiconductor. Unfortunately, the following problems may occur due to any of high-melting-point metals generally used for the barrier metal, such as Ti, Hf, Zr, Mo, Ta, W, Nb, V, and Cr.

For example, use of high-melting-point metals each having a large absolute value of negative free energy of oxide formation, such as Ti, Hf, and Zr, causes an oxidation-reduction reaction of the metal and the underlying oxide semiconductor, which disadvantageously induces deviation from stoichiometry of the oxide semiconductor, leading to degradation in TFT characteristics and separation of the Cu film.

On the other hand, use of high-melting-point metals each having a small absolute value of negative free energy of oxide formation, such as Mo, Ta, W, Nb, V, and Cr, causes no oxidation-reduction reaction of the metal and the underlying oxide semiconductor unlike the above-described metals such as Ti, which therefore does not induce deviation from stoichiometry of the oxide semiconductor. Each of these metals, however, has substantially no etching selectivity against the underlying oxide semiconductor thin film. In other words, it is less likely to occur that only the upper high-melting-point metal is selectively etched while the underlying oxide semiconductor layer is left unetched. This results in undesirable etching of the underlying oxide semiconductor layer during formation of an interconnection pattern by wet etching using an acid-based etchant. As a measure for this, in general, as illustrated in FIG. 1, an etch stop layer 12 of an insulator such as SiO₂ is provided as a protective layer on an oxide semiconductor thin film 4 as a channel layer.

This measure, however, results in a complicated process, and requires a special photomask for processing of the etch stop layer, which disadvantageously leads to a significant increase in steps of TFT manufacturing.

Such a reduction in productivity in wet etching associated with introduction of the etch stop layer also occurs more or less with each of the high-melting-point metals such as Ti.

Such problems may occur not only with Cu but also with an Al film used as the interconnection material.

In this way, the above-described problems are found in the case where any of the high-melting-point-metal barrier metal layers is used. To solve the problems, it is desired to provide an interconnection structure having excellent fine-processability despite providing no etch stop layer.

Furthermore, particularly when a high-melting-point-metal barrier metal layer including, for example, Ti is used, it is desired to provide an interconnection structure that allows the above-described problems to be solved, causes no deviation from stoichiometry of the oxide semiconductor even after heat treatment, secures excellent TFT characteristics, and causes no separation of a metal interconnection film configuring, for example, a source or drain electrode. In other words, it is desired to provide an interconnection structure that allows a stable interface to be formed between the oxide semiconductor and the metal interconnection film.

A first object of the invention, which has been made in light of the above-described circumstances, is to provide an interconnection structure of a display such as an organic EL display or a liquid crystal display, the interconnection structure having excellent fine-processability despite providing no additional etch stop layer, and provide the display including such an interconnection structure.

A second object of the invention is to provide an interconnection structure of a display such as an organic EL display or a liquid crystal display, the interconnection structure allowing a stable interface to be formed between the oxide semiconductor layer and a metal interconnection film configuring, for example, a source or drain electrode, and provide the display including such an interconnection structure.

### Means for Solving the Problems

The present invention provides the following interconnection structure and display.

(1) An interconnection structure including a substrate, a semiconductor layer for a thin film transistor on the substrate, a metal interconnection film on the semiconductor layer, and a barrier layer between the semiconductor layer and the metal interconnection film, wherein

the semiconductor layer is composed of oxide semiconductor, and

the barrier layer has a stacked structure of a high-melting-point-metal thin film and a Si thin film, the Si thin film being directly connected to the semiconductor layer.

(2) The interconnection structure according to (1), wherein the high-melting-point-metal thin film is configured of one of a pure Ti thin film, a Ti alloy thin film, a pure Mo thin film, and a Mo alloy thin film.

(3) The interconnection structure according to (1) or (2), wherein the Si thin film has a thickness of 3 to 30 nm.

(4) The interconnection structure according to any one of (1) to (3), wherein the metal interconnection film is configured of one of a pure Al film, an Al alloy film containing at least 90 at % Al, a pure Cu film, and a Cu alloy film containing at least 90 at % Cu.

(5) The interconnection structure according to any one of (1) to (4), wherein the oxide semiconductor is composed of an oxide containing at least one element selected from a group consisting of In, Ga, Zn, and Sn.

(6) A display including the interconnection structure according to any one of (1) to (5).

### Advantage of the Invention

According to the present invention, an interconnection structure having an oxide semiconductor layer includes a Si thin film, which is interposed between a traditional high-melting-point-metal barrier metal layer (high-melting-point-metal thin film) and the oxide semiconductor thin film, as a barrier layer that suppresses an oxidation-reduction reaction of a metal as an interconnection material with the oxide semiconductor thin film while effectively preventing diffusion of the metal into the oxide semiconductor, which results in stable TFT characteristics, and consequently a display having improved quality can be provided.

Moreover, according to the invention, the Si thin film serves as an etch stop layer during wet etching; hence, an interconnection structure having excellent fine-processability can be provided despite providing no etch stop layer unlike in the past. In other words, the metal interconnection film and the high-melting-point-metal barrier metal layer on the Si thin film are sequentially patterned by wet etching, and then the Si thin film is dry-etched, or is made nonconductive (the entire Si film is changed into an insulator film such as a Si oxide film) by, for example, plasma oxidation, so that a display having excellent TFT characteristics can be provided even after fine processing. In this way, according to the invention, formation of the etch stop layer can be omitted, and thus the number of masks can be decreased in a TFT manufacturing process, and consequently a display, which is inexpensive and high in production efficiency, can be provided.

### BRIEF DESCRIPTION OF THE DRAWINGS

FIG. 1 is a cross sectional view schematically illustrating a configuration of a traditional interconnection structure having an etch stop layer.

FIG. 2 is a cross sectional view schematically illustrating a configuration of an interconnection structure according to a first embodiment (5-mask process) of the invention, showing exemplary formation of a channel section and an opening other than TFT through dry etching of a Si thin film.

FIG. 3 is a cross sectional view schematically illustrating another configuration of an interconnection structure according to the first embodiment (5-mask process) of the invention, showing exemplary formation of a channel section and an opening other than TFT through dry etching of a Si thin film.

FIG. 4 is a cross sectional view schematically illustrating a configuration of an interconnection structure according to a second embodiment (4-mask process) of the invention, showing exemplary formation of a channel section and an opening other than TFT through dry etching of a Si thin film.

FIG. 5 is a cross sectional view schematically illustrating another configuration of an interconnection structure according to the second embodiment (4-mask process) of the invention, showing exemplary formation of a channel section and an opening other than TFT through oxidation of a Si thin film.

FIGS. 6(a) and 6(b) are a top view (FIG. 6(a)) and a cross sectional view (FIG. 6(b)) schematically illustrating a configuration of a sample for evaluating an undercut level of a dry-etched Si film in an Example.

FIG. 7 is a cross-sectional TEM image (at a magnification of 1,500,000) of No. 12 (a case of the invention) in Table 1.

FIG. 8 is a cross-sectional TEM image (at a magnification of 900,000) of No. 9 (a traditional case) in Table 1.

FIG. 9 is a cross-sectional TEM image (at a magnification of 300,000) of No. 9 (the traditional case) in Table 1.

### Mode for Carrying Out the Invention

The inventors have conducted various investigations to provide an interconnection structure that allows a stable interface to be formed between a metal interconnection film for a source or drain electrode and an oxide semiconductor layer, which is disposed below the metal interconnection film as viewed from the substrate, and has excellent fine-processability despite providing no etch stop layer. As a result, the inventors have found that if a traditional structure, which has a high-melting-point-metal barrier metal layer interposed between an oxide semiconductor layer as a base and a metal interconnection film, is modified into a structure where a Si thin film is interposed between the high-melting-point-metal barrier metal layer and the oxide semiconductor layer, and the Si thin film is directly connected to the oxide semiconductor layer, (1) an oxidation-reduction reaction of a metal composing the metal interconnection film with the oxide semiconductor, which may occur with a high-melting-point-metal barrier metal layer including, for example, Ti, is suppressed, and diffusion of the metal into the oxide semiconductor and diffusion of a compositional element of the oxide semiconductor into the metal interconnection film are prevented, and (2) the Si thin film also serves as an etch stop layer during wet etching, and thus protects the oxide semiconductor of a channel section of TFT from damage during wet etching, and therefore an interconnection structure, which has excellent fine-processability and excellent TFT characteristics after fine processing, is produced. Consequently, the inventors have finally completed the invention.

In this way, the interconnection structure of the invention is characterized by having a barrier layer, which is configured of a high-melting-point-metal thin film and a Si thin film, between the oxide semiconductor layer and the metal interconnection film, the Si thin film being directly connected to the oxide semiconductor layer. If a barrier metal layer including, for example, Ti is used as the high-melting-point-metal thin film, the effects of (1) and (2) are achieved. If a barrier metal layer including, for example, Mo or Ta is used as the high-melting-point-metal thin film, the effect (2) is achieved.

### First Embodiment with 5-Mask Process

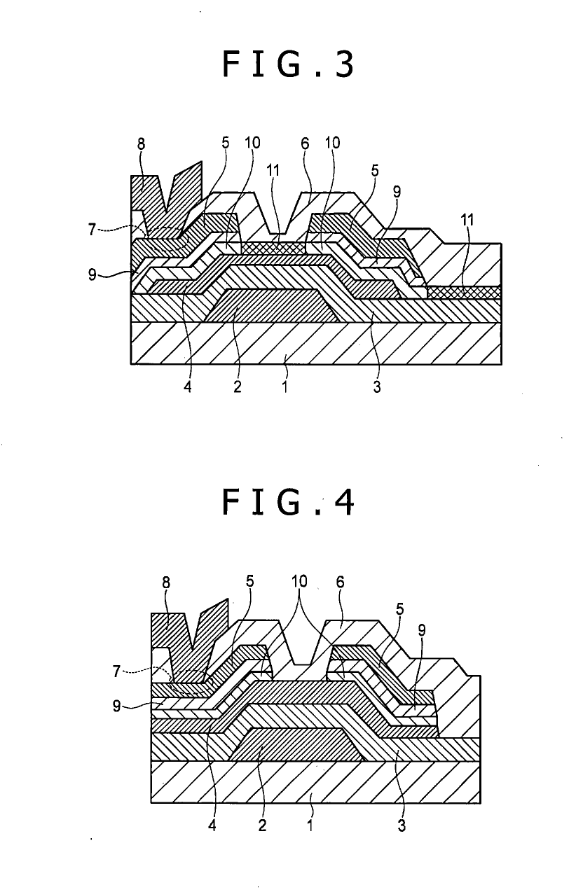

A first embodiment, with a 5-mask process, of an interconnection structure according to the invention is now described with reference to FIGS. 2 and 3. Although the first embodiment and a second embodiment described later each exemplify a process assuming that a liquid crystal display is used, it will be appreciated that the invention is not limited thereto. For example, in the case where the interconnection structure is applied to an organic EL display, a different number of masks may be naturally used in a process. In FIG. 2, a channel section and a portion other than TFT (hereinafter, referred to as opening) are formed through wet etching of a metal interconnection film and a high-melting-point metal thin film 9 configuring source/drain electrodes 5, and then dry etching of a Si thin film 10. In FIG. 3, the interconnection structure is formed in the same way as that of FIG. 2 except that the Si thin film 10 is oxidized (made nonconductive) into a Si oxide film 11 to form the channel section and the opening.

FIGS. 2 and 3 and a method of manufacturing an interconnection structure described later each unlimitedly show an exemplary, but not limitative, preferred embodiment of the invention. For example, although FIGS. 2 and 3 each illustrate bottom-gate TFT, the TFT is not limited thereto, and may be top-gate TFT including a gate insulator film and a gate electrode in this order on an oxide semiconductor layer. Moreover, although a Ti thin film is exemplified as the high-melting-point-metal barrier metal layer (high-melting-point-metal thin film) 9 hereinafter, any of other generally-used high-melting-point metals other than Ti may be used without limitation.

As illustrated in FIGS. 2 and 3, the interconnection structure of the first embodiment according to the invention includes a gate electrode 2, a gate insulator film 3, and an oxide semiconductor layer 4 in this order on a substrate 1. The source/drain electrodes 5 and a protective film (insulator film) 6 are provided in this order on the oxide semiconductor layer 4, and a transparent conductive film 8 is electrically connected to the drain electrode 5 through a contact hole 7.

The interconnection structure is characterized by having the high-melting-point metal thin film 9 including, for example, Ti, and having the Si thin film 10 between the source/drain electrodes 5 and the oxide semiconductor layer 4. As illustrated in FIGS. 2 and 3, the Si thin film 10 is directly connected to the oxide semiconductor layer 4. The Si thin film 10 suppresses an oxidation-reduction reaction of the source/drain electrodes with the underlying oxide semiconductor layer due to thermal history received after formation of the source/drain electrodes, for example, during formation of the protective layer, and serves as a barrier layer that may prevent diffusion of metal into the semiconductor layer and diffusion of semiconductor into the source/drain electrodes. Furthermore, the Si thin film 10 also serves as an etch stop layer during wet etching, and thus protects the oxide semiconductor layer 4 of the channel section of the TFT from damage during wet etching. Thus, formation of the Si thin film 10 leads to a significant improvement in fine-processability and in TFT characteristics after fine processing.

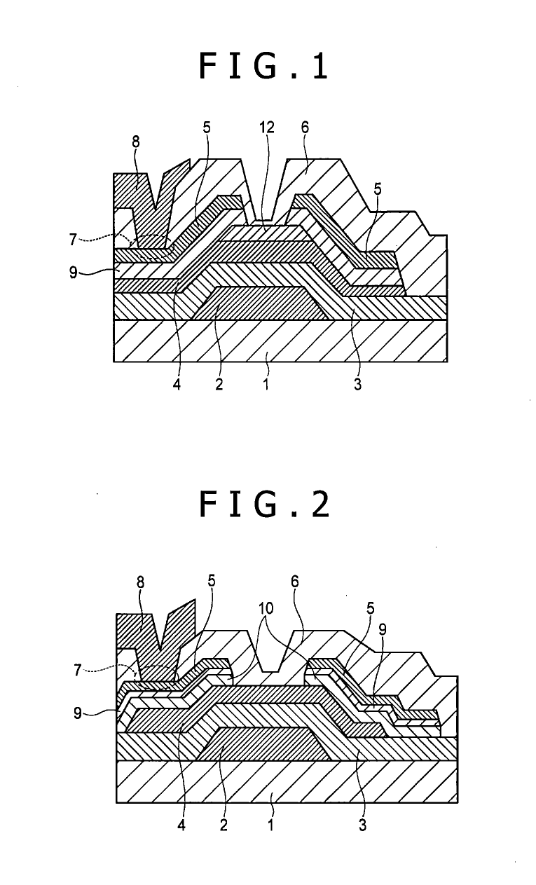

Specifically, the invention is most distinctively characterized by having the Si thin film 10 between the high-melting-point metal thin film 9 including, for example, Ti, which is generally used as the barrier metal layer, and the oxide semiconductor layer 4. The above-described traditional interconnection structure of FIG. 1 includes no Si thin film 10, and includes the high-melting-point metal thin film 9 and the oxide semiconductor layer 4 directly connected to each other.

The Si thin film 10, which is formed by a sputtering process or a chemical vapor deposition process such as CVD as described later, may contain elements inevitably mixed therein during film formation, for example, oxygen, nitrogen, and hydrogen.

The Si thin film 10 preferably has a thickness of approximately 3 nm or more in order to allow the above-described functions and effects to be sufficiently exhibited. More preferably, the thickness is 5 nm or more. On the other hand, excessively large thickness may cause undercut in the Si thin film 10 during dry etching, leading to degradation in fine-processability. Moreover, such large thickness may cause degradation in TFT characteristics after the Si thin film 10 is made nonconductive. From such a viewpoint, the thickness of the Si thin film 10 is preferably up to 30 nm, and more preferably up to 15 nm.

Although the Si thin film 10 may be of either an undoped type or an n- or p-doped type, doped semiconductor, which can be formed by DC sputter, is preferred in consideration of mass-productivity. In Examples described later, n-type semiconductor was used for any of oxide semiconductor layers and Si thin films.

To repeatedly describe, the interconnection structure is most distinctively characterized by having the Si thin film 10 between the high-melting-point metal thin film 9 including, for example, Ti and the oxide semiconductor layer 4. There is no limited requirement other than the Si thin film 10, and any of configurations generally used for the interconnection structure may be appropriately selectively used.

For example, the high-melting-point metal thin film 9 may be composed not only of the Ti material, but also of a high-melting-point metal typically used for any barrier metal layer for a display, such as Mo, Ta, Zr, Nb, W, V, and Cr. The Ti material includes not only pure Ti but also Ti alloy. The term “pure Ti” refers to Ti exclusively containing inevitable impurities other than any third element added to improve characteristics. The term “Ti alloy” contains approximately 50 at % or more Ti, and the remainder including any alloy element other than Ti and inevitable impurities. The Ti alloy includes generally used alloys such as Ti—Mo, Ti—W, and Ti—Ni.

The high-melting-point metal materials other than Ti, such as pure Mo, Mo alloy, pure Ta, and Ta alloy, are each defined as in the Ti material. Each of the high-melting-point metal materials preferably has a thickness of 5 nm or more to sufficiently exhibit the barrier effect. More preferably, the thickness is 10 nm or more. On the other hand, excessively large thickness may lead to degradation in fine-processability; hence, the thickness is preferably up to 80 nm, and more preferably up to 50 nm.

As the metal composing the source/drain electrodes 5, one of pure Al and an Al alloy film containing 90 at % or more Al, or one of pure Cu and a Cu alloy film containing 90 at % or more Cu is preferably used in light of electric resistance.

The term “pure Al” refers to Al exclusively containing inevitable impurities other than any third element added to improve characteristics. The term “Al alloy” contains approximately 90 at % or more Al, and the remainder including any alloy element other than Al and inevitable impurities. The “alloy element other than Al” includes any alloy element having low electric resistance, examples of which specifically include Si, Cu, Nd, and La. The Al alloy containing any of such alloy elements is preferably controlled in electric resistivity to be 5.0×10⁻⁶ Ω·cm or less through adjusting the added amount of the element and thickness of the film.

The term “pure Cu” refers to Cu exclusively containing inevitable impurities other than any third element added to improve characteristics. The term “Cu alloy” contains approximately 90 at % or more Cu, and the remainder including any alloy element other than Cu and inevitable impurities. The “alloy elements other than Cu” include any alloy element having low electric resistance, examples of which specifically include Mn, Ni, Ge, Mg, and Ca. The Cu alloy containing any of such alloy elements is preferably controlled in electric resistivity to be 4.0×10⁻⁶ Ω·cm or less through adjusting the added amount of the alloy element and of thickness of the film.

The oxide composing the oxide semiconductor layer 4 preferably contains at least one element selected from a group consisting of In, Ga, Zn, and Sn. Specific examples of the oxide include In-contained oxide semiconductors such as In—Ga—Zn—O, In—Zn—Sn—O and In—Zn—O, and In-free Zn-contained oxide semiconductors such as ZnO, Zn—Sn—O, Ga—Zn—Sn—O, and Al-Ga—Zn—O. Each of the oxide semiconductors may have any compositional ratio within a normal range without limitation.

The substrate 1 may be any substrate that is typically used for a display without limitation, examples of which include transparent substrates such as an alkali-free glass substrate, a high-strain-point glass substrate, and a soda-lime glass substrate, Si substrates, metal sheets such as a stainless sheet, and resin substrates such as a PET film.

Moreover, a metal material used for the gate electrode 2 may be any metal material typically used for a display without limitation, and includes metals having low electric resistivity such as Al and Cu, and alloys thereof. Specifically, the above-described metal materials (pure Al, Al alloy, pure Cu, and Cu alloy) used for the source/drain electrodes 5 are each preferably used. The gate electrode 2 and the source/drain electrodes 5 may be composed of the same metal material.

Moreover, each of the gate insulator film 3 and the protective film (insulator film) 6 may be any film typically used for a display without limitation, and is typically exemplified by a silicon oxide film, a silicon nitride film, and a silicon oxynitride film. In addition, any of oxides such as Al₂O₃ and Y₂O₃, and any stack of the oxides may be used for the films.

Moreover, a material used for the transparent conductive film 8 may be any material typically used for a display without limitation, examples of which include oxide conductors such as ITO, IZO, and ZnO.

A preferred embodiment of a method for manufacturing the interconnection structure is now described though the invention is not limited thereto.

First, the gate electrode 2 and the gate insulator film 3 are sequentially formed on the substrate 1. The formation process may be any process typically used for a display without limitation, examples of which include a CVD (Chemical Vapor Deposition) process.

The oxide semiconductor layer 4 is then formed. The oxide semiconductor layer 4 is preferably formed by a DC or RF sputtering process using a target having the same composition as that of the oxide semiconductor layer 4.

The oxide semiconductor layer 4 is then patterned through wet etching. It is preferred to perform heat treatment (pre-anneal) immediately after the patterning in order to improve quality of the oxide semiconductor layer 4, which improves transistor characteristics such as On-current and field-effect mobility, leading to improvement in transistor performance. Examples of the pre-anneal condition include heat treatment at about 250 to 400° C. for about 1 to 2 hr in an air or oxygen atmosphere.

After the pre-annealing, the Si thin film 10 as a characterizing portion of the invention, the Ti thin film 9, and the source/drain electrodes 5 are deposited to form the channel section of the TFT and the opening other than the TFT. Specifically, the predetermined Si thin film 10, the Ti thin film 9, and the metal film (a pure Cu film, for example) configuring the source/drain electrodes 5 are beforehand formed in sequence by a sputtering process, and are then patterned. The patterning method used in the first embodiment is now described with reference to FIGS. 2 and 3 though the invention is not limited thereto.

In detail, as illustrated in FIG. 2, the metal film configuring the source/drain electrodes 5 and the Ti thin film 9 are wet-etched, and then the Si thin film 10 is dry-etched, so that the channel section and the opening other than the TFT can be formed. Any of typically used wet etching processes may be used as the wet etching process without limitation. Any of typically used dry etching processes may be used as the dry etching process without limitation. Examples of the dry etching process include processing with plasma of a mixed gas of CF₄ and O₂ or a mixed gas of SF₆ and O₂.

Alternatively, as illustrated in FIG. 3, the metal film configuring the source/drain electrodes 5 and the Ti thin film 9 are wet-etched, and then the Si thin film 10 is oxidized (made nonconductive) into a Si oxide insulator film so that the channel section and the opening other than the TFT can be formed. Si is appropriately oxidized by any of oxidizing methods, which are typically used to make a conductor to be nonconductive, without limitation as long as Si can be made nonconductive thereby. Specifically, plasma irradiation using N₂O is typically exemplified. While the plasma irradiation condition varies depending on the thickness of the Si thin film and other factors such as a plasma apparatus type to be used, power density, and powering time, the irradiation condition may be appropriately adjusted depending on the thickness of the Si thin film such that the Si thin film is entirely changed into a Si oxide film.

In the first embodiment, although each of the dry etching process illustrated in FIG. 2 and the process for making a conductor nonconductive illustrated in FIG. 3 may be used, the dry etching process is preferably used in consideration of uniformity in a substrate surface.

The transparent conductive film 8 is electrically connected to the drain electrode 5 through the contact hole 7 in a usual manner to produce the interconnection structure of the invention.

### Second Embodiment with 4 Mask Process

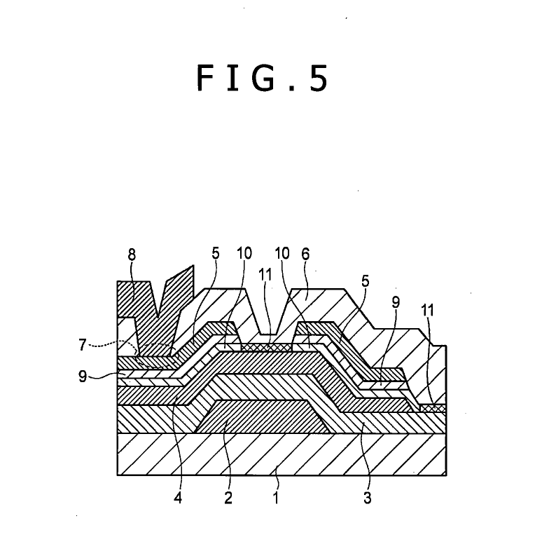

A second embodiment, with a 4-mask process, of the interconnection structure according to the invention is now described with reference to FIGS. 4 and 5. In FIG. 4, a channel section and an opening other than TFT are formed through wet etching of a metal interconnection film and a high-melting-point metal thin film 9 configuring source/drain electrodes 5, and then dry etching of a Si thin film 10. In FIG. 5, the interconnection structure is formed in the same way as that of FIG. 4 except that the Si thin film 10 is oxidized (made nonconductive) into a Si oxide film 11 to form the channel section and the opening.

In addition, while patterning is performed with usual masks (5-mask process) in the first embodiment (FIGS. 2 and 3), halftone exposure is performed through a halftone mask, and therefore the number of masks to be used can be decreased to four (4-mask process) in the second embodiment (FIGS. 4 and 5). The halftone exposure can represent three exposure levels of an exposed portion, semi-exposed portion, and unexposed portion, thus allowing formation of two photo resists (photosensitive materials) having different thicknesses after development. Thus, patterning can be performed with a smaller number of photomasks than in usual by using the photo resists having different thicknesses, leading to an increase in production efficiency.

Other steps are the same as in the first embodiment; hence, description thereof is omitted. The interconnection structures of FIGS. 4 and 5 are marked with the same numerals as those in FIGS. 2 and 3, respectively. Details of the individual elements should be referred to the first embodiment.

### EXAMPLES

Although the invention is now described in detail with Examples, the invention should not be limited thereto, and modifications or alterations thereof may be made within the scope without departing from the gist described before and later, all of which are included in the technical scope of the invention.

### Example 1

In Example 1, samples were prepared by a process below (using a pure Ti film as the high-melting-point metal thin film), and were used to evaluate adhesion of the oxide semiconductor to the Si film, diffusion of any compositional element of the oxide semiconductor into the metal interconnection film, and dry etching performance based on undercut length of the dry-etched Si thin film, and to examine TFT characteristics after making the Si film nonconductive.

### (Preparation of Samples for Adhesion Test)

First, a gate insulator film of SiO₂ was formed by 200 nm on a glass substrate (EAGLE XG from Corning Inc.; 100 nm in diameter and 0.7 mm in thickness). The gate insulator film was formed by a plasma CVD process using a mixed gas of SiH₄ and N₂O as a carrier gas at deposition power of 100 W and deposition temperature of 300° C.

Various oxide semiconductor layers shown in Tables 1 to 8 were each then formed on the gate insulator film by a sputtering process using a certain target. The sputtering conditions were as shown below. Each of used targets had a composition adjusted to produce each desired semiconductor layer.

Target: In—Ga—Zn—O (IGZO)
Zn—Sn—O (ZTO)
Ga—Zn—Sn—O (GZTO)
In—Zn—Sn—O (IZTO)

Substrate temperature: Room temperature

Gas pressure: 5 mTorr

Oxygen partial pressure: O₂/(Ar+O₂)=4%

Thickness: 50 nm

Pre-anneal was then performed at 350° C. for 1 hr under the atmospheric pressure in order to improve film quality.

Each of Si films having thicknesses shown in Tables 1 to 8, a pure Ti film 30 nm in thickness, and a pure-Cu metal interconnection film 250 nm in thickness were then formed on each of the above-described oxide semiconductor films by a DC magnetron sputtering process.

The sputtering conditions of the Si films, the pure Ti film, and the pure-Cu were as follows.

Target: Si target (for Si film)
Pure Ti target (for pure Ti film)
Pure Cu target (for pure Cu film)

Deposition temperature: Room temperature

Carrier gas: Ar

Gas pressure: 2 mTorr

### (Adhesion Test to Oxide Semiconductor)

Each sample produced as above was heat-treated at 350° C. for 30 min, and adhesion between the heat-treated sample and the oxide semiconductor (in detail, adhesion between the Si film and the oxide semiconductor) was evaluated by a peeling test with a tape in accordance with a tape separation test defined by JIS-K5600.

In detail, a surface (on a side close to the pure Cu film) of each sample was incised (into 5×5 squares) on a grid at 1 mm intervals by a box cutter. A black polyester tape from ULTRA TAPE Co., Ltd. (Ultra Tape #6570) was then firmly attached onto the surface. The tape was then peeled while being held at a peeling angle of 60°. The number of blocks of the grid, which had not been separated by the tape, was then counted to obtain a ratio (film residual ratio) of the blocks to all blocks. Such measurement was repeated three times for each sample, and the average over the three measurements was determined to be the film residual ratio of the sample.

In the Example 1, the film residual ratio, which was calculated as above, was determined to be A (good) for 90% or more, B (pretty good) for 70% to less than 90%, and C (bad) for less than 70%, where A and B were acceptable (good in adhesion between the film and the oxide semiconductor layer).

(Diffusion of Compositional Element of Oxide Semiconductor Layer into Cu Film)

Diffusion of a compositional element of the oxide semiconductor layer into the Cu film was checked for each sample by SIMS (Secondary Ion Mass Spectrometry). Such experiment was conducted at 1 keV with a primary ion of O₂⁺. The criterion of the diffusion was as follows. A structure including an oxide semiconductor layer, Mo and Cu stacked in this order from a bottom side, in which none of the compositional elements (m, Ga, Zn, and Sn) of the oxide semiconductor layer diffused into the Cu film, was used as a reference. While a certain slight signal intensity of each of the compositional elements (m, Ga, Zn, and Sn) of the oxide semiconductor layer was shown in the Cu film of the reference structure, it was determined that a sample showing a signal intensity at least 5 times as large as the certain signal intensity was C (bad, or diffusion), a sample showing a signal intensity 3 to less than 5 times as large as the certain signal intensity was B (pretty good, or substantially no diffusion), and a sample showing signal intensity less than 3 times as large as the certain signal intensity was A (good, or no diffusion).

In the Example 1, A and B were determined to be acceptable.

### (Evaluation of Dry Etching Performance Based on Undercut Length of Dry-Etched Si Film)

An undercut level of each dry-etched Si film was evaluated. In general, since dry etching of a Si film is mainly performed by radicals, the Si film is also etched in a lateral direction by dry etching, causing undercut of the Si film. In the Example 1, dry etching performance was evaluated based on an undercut level of each dry-etched Si film.

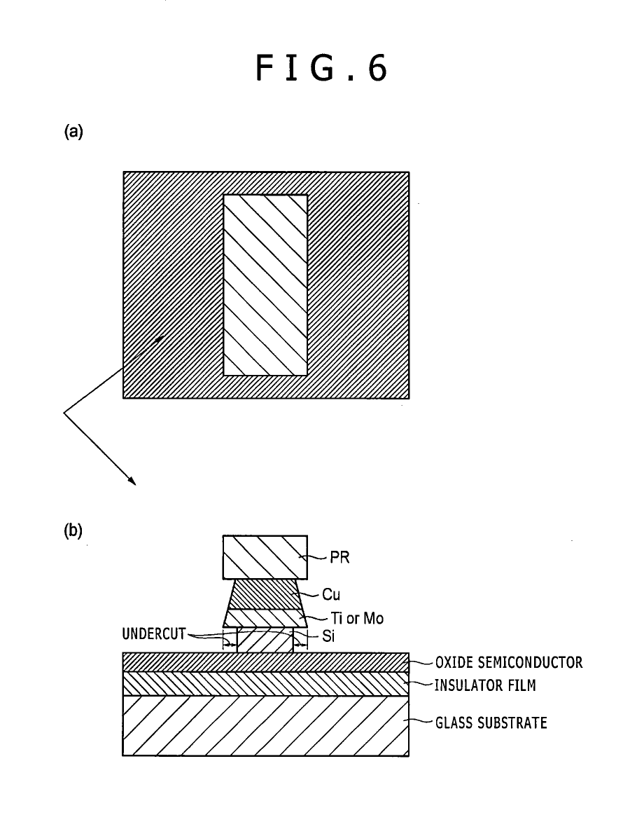

Specifically, for each sample, the photo resist layer was first patterned by photolithography, and the patterned resist was used as a mask to wet-etch the pure Cu film and the pure Ti film. A mixed-acid etchant (phosphoric acid/sulfuric acid/nitric acid/acetic acid=50/10/5/10) was used as the etchant for the pure Cu film, and dilute hydrofluoric acid (hydrofluoric acid/water=1/50) was used as the etchant for the pure Ti film. The Si film was then dry-etched to form a pattern as shown in FIGS. 6(a) and 6(b). FIG. 6(a) is a top view of a resultant pattern, and FIG. 6(b) is a cross sectional view of the pattern. In FIG. 6(b), PR is an abbreviation of Photo Resist. The dry etching was performed by RIE (Reactive Ion Etching) with a mixed gas of 33.3% SF6, 26.7% O₂, and 40% Ar. After the Si film was etched, over etching was performed by 100% in terms of the Si film. A section of an interconnection of each etched sample was observed by SEM (Scanning Electron Microscope) to measure the undercut length of the Si film.

In the Example 1, undercut of each Si film was evaluated in accordance with the criterion below, where A and B were determined to be good in dry etching performance.

### (Criterion)

A (good) . . . 15 nm or less

B (pretty good) . . . 16 to 30 nm

C (bad) . . . 31 nm or more

(Evaluation of TFT Characteristics after Making Si Film Nonconductive)

After the Si film was made nonconductive, TFT characteristics were evaluated.

In detail, TFT shown in FIG. 3 was prepared as follows. First, a Ti thin film as a gate electrode 100 nm thick and a gate insulator film of SiO₂ 200 nm thick were sequentially deposited on a glass substrate (EAGLE XG from Corning Inc.; 100 nm in diameter and 0.7 mm in thickness). The gate electrode was formed by a DC sputtering process using a pure Ti target 4 inches in diameter under conditions of deposition temperature of room temperature, deposition power of 300 W, carrier gas of Ar, and gas pressure of 2 mTorr. The gate insulator film was formed by a plasma CVD process using a mixed gas of SiH₄ and N₂O as a carrier gas at deposition power of 100 W and deposition temperature of 300° C.

Various oxide semiconductor thin films shown in Tables 1 to 8 were each then formed on the gate insulator film by a sputtering process using a certain target. The sputtering conditions were as shown below. Each of used targets had a composition adjusted to produce each desired semiconductor layer.

Target: In—Ga—Zn—O (IGZO)
Zn—Sn—O (ZTO)
Ga—Zn—Sn—O (GZTO)
In—Zn—Sn—O (IZTO)

Substrate temperature: Room temperature

Gas pressure: 5 mTorr

Oxygen partial pressure: O₂/(Ar+O₂)=4%

Thickness: 50 nm

Each of the oxide semiconductor thin films formed as above was then patterned through photolithography and wet etching.

An “ITO-07N” from Kanto Chemical Co., Ltd was used as the etchant.

After the oxide semiconductor thin film was patterned, pre-anneal was performed at 350° C. for 1 hr under the atmospheric pressure in order to improve film quality.

After the pre-anneal, each of Si films having thicknesses shown in Tables 1 to 8, a pure Ti film 30 nm in thickness, and a pure-Cu metal interconnection film 250 nm in thickness were formed. Specifically, the Si film, the pure Ti film, and the pure-Cu film were sequentially formed by a sputtering process, and then the Cu film and the Ti film were patterned through photolithography and wet etching. The sputtering conditions were as shown below. A mixed-acid etchant (phosphoric acid/sulfuric acid/nitric acid/acetic acid=50/10/5/10) was used as the etchant for the pure Cu film, and dilute hydrofluoric acid (hydrofluoric acid/water=1/50) was used as the etchant solution for the pure Ti film.

Target: Si target (for Si film)
Pure Ti target (for pure Ti film)
Pure Cu target (for pure Cu film)

Deposition temperature: Room temperature

Carrier gas: Ar

Gas pressure: 2 mTorr

The Si film in the channel section was then oxidized into a Si oxide film. Specifically, Si in the channel section was oxidized through N₂O plasma irradiation. The plasma irradiation conditions were as follows.

Gas: N₂O

Substrate temperature: 280° C.

Power: 100 W

Gas pressure: 133 Pa

Gas flow rate: 100 sccm

Time: 5 min

The films were then subjected to ultrasonic cleaning in acetone by an ultrasonic cleaner to remove unnecessary photoresist in order to adjust the channel length and the channel width of TFT to be 10 μm and 200 μm, respectively.

The transistor characteristics (drain current-gate voltage characteristics, or I_{d}-V_{g} characteristics) of each TFT produced in this way were examined in the following way.

The transistor characteristics were measured with a semiconductor parameter analyzer “4156C” from Agilent Technology Inc. Detailed measurement conditions were as shown below. In the Example 1, I_{d} at V_{g} of −30 V was defined as OFF current I_{off} (A), and I_{d} at V_{g} of 30 V was defined as ON current Iₒₙ(A). A ratio Iₒₙ/I_{off} was then calculated.

Source voltage: 0 V

Drain voltage: 10 V

Gate voltage: −30 to 30 V (measurement interval: 1 V)

Based on the ratio Iₒₙ/I_{off} calculated in this way, TFT characteristics after making the Si film nonconductive were evaluated according the criterion below. In the Example 1, A and B were determined to be excellent in TFT characteristics.

### (Criterion)

A (good) . . . ratio Iₒₙ/I_{off} of five or more digits

B (pretty good) . . . ratio Iₒₙ/I_{off} of three to less than five digits

C (bad) . . . ratio Iₒₙ/I_{off} of less than three digits

Tables 1 to 8 collectively show the results.

TABLE 1

| | Compositional | | | Si film | Characteristics | | | | |
|---|---|---|---|---|---|---|---|---|---|
| | ratio of IGZO | | | Thickness | Diffu- | | | Similarity to | Evalu- |
| No. | In | Ga | Zn | (nm) | sion | Adhesion | Undercut | insulator | ation |
| 1 | 1 | 1 | 1 | — | C | C | — | — | C |
| 2 | 1 | 1 | 1 | 3 | B | B | A | A | B |
| 3 | 1 | 1 | 1 | 5 | A | A | A | A | A |
| 4 | 1 | 1 | 1 | 10 | A | A | A | A | A |
| 5 | 1 | 1 | 1 | 15 | A | A | A | A | A |
| 6 | 1 | 1 | 1 | 20 | A | A | B | B | B |
| 7 | 1 | 1 | 1 | 30 | A | A | B | B | B |
| 8 | 1 | 1 | 1 | 40 | A | A | C | C | C |
| 9 | 2 | 2 | 1 | — | C | C | — | — | C |
| 10 | 2 | 2 | 1 | 3 | B | B | A | A | B |
| 11 | 2 | 2 | 1 | 5 | A | A | A | A | A |
| 12 | 2 | 2 | 1 | 10 | A | A | A | A | A |
| 13 | 2 | 2 | 1 | 15 | A | A | A | A | A |
| 14 | 2 | 2 | 1 | 20 | A | A | B | B | B |
| 15 | 2 | 2 | 1 | 30 | A | A | B | B | B |
| 16 | 2 | 2 | 1 | 40 | A | A | C | C | C |

TABLE 2

| | Compositional ratio | | Si film | Characteristics | | | | |
|---|---|---|---|---|---|---|---|---|
| | (atomic ratio) of ZTO | | Thickness | Diffu- | | | Similarity to | Evalu- |
| No. | Zn/(Zn + Sn) | Sn/(Zn + Sn) | (nm) | sion | Adhesion | Undercut | insulator | ation |
| 1 | 0.5 | 0.5 | — | C | C | — | — | C |
| 2 | 0.5 | 0.5 | 3 | B | B | A | A | B |
| 3 | 0.5 | 0.5 | 5 | A | A | A | A | A |
| 4 | 0.5 | 0.5 | 10 | A | A | A | A | A |
| 5 | 0.5 | 0.5 | 15 | A | A | A | A | A |
| 6 | 0.5 | 0.5 | 20 | A | A | B | B | B |
| 7 | 0.5 | 0.5 | 30 | A | A | B | B | B |
| 8 | 0.5 | 0.5 | 40 | A | A | C | C | C |
| 9 | 0.67 | 0.33 | — | C | C | — | — | C |
| 10 | 0.67 | 0.33 | 3 | B | B | A | A | B |
| 11 | 0.67 | 0.33 | 5 | A | A | A | A | A |
| 12 | 0.67 | 0.33 | 10 | A | A | A | A | A |
| 13 | 0.67 | 0.33 | 15 | A | A | A | A | A |
| 14 | 0.67 | 0.33 | 20 | A | A | B | B | B |
| 15 | 0.67 | 0.33 | 30 | A | A | B | B | B |
| 16 | 0.67 | 0.33 | 40 | A | A | C | C | C |
| 17 | 0.75 | 0.25 | — | C | C | — | — | C |
| 18 | 0.75 | 0.25 | 3 | B | B | A | A | B |
| 19 | 0.75 | 0.25 | 5 | A | A | A | A | A |
| 20 | 0.75 | 0.25 | 10 | A | A | A | A | A |
| 21 | 0.75 | 0.25 | 15 | A | A | A | A | A |
| 22 | 0.75 | 0.25 | 20 | A | A | B | B | B |
| 23 | 0.75 | 0.25 | 30 | A | A | B | B | B |
| 24 | 0.75 | 0.25 | 40 | A | A | C | C | C |

TABLE 3

| | Compositional ratio (atomic ratio) | | | Si film | Characteristics | | | | |
|---|---|---|---|---|---|---|---|---|---|
| | of oxide semiconductor | | | Thickness | Diffu- | | | Similarity to | Evalu- |
| No. | Ga/(Zn + Sn + Ga) | Zn/(Zn + Sn) | Sn/(Zn + Sn) | (nm) | sion | Adhesion | Undercut | insulator | ation |
| 1 | 0.05 | 0.5 | 0.5 | — | C | C | — | — | C |
| 2 | 0.05 | 0.5 | 0.5 | 3 | B | B | A | A | B |
| 3 | 0.05 | 0.5 | 0.5 | 5 | A | A | A | A | A |
| 4 | 0.05 | 0.5 | 0.5 | 10 | A | A | A | A | A |
| 5 | 0.05 | 0.5 | 0.5 | 15 | A | A | A | A | A |
| 6 | 0.05 | 0.5 | 0.5 | 20 | A | A | B | B | B |
| 7 | 0.05 | 0.5 | 0.5 | 30 | A | A | B | B | B |
| 8 | 0.05 | 0.5 | 0.5 | 40 | A | A | C | C | C |
| 9 | 0.05 | 0.67 | 0.33 | — | C | C | — | — | C |
| 10 | 0.05 | 0.67 | 0.33 | 3 | B | B | A | A | B |
| 11 | 0.05 | 0.67 | 0.33 | 5 | A | A | A | A | A |
| 12 | 0.05 | 0.67 | 0.33 | 10 | A | A | A | A | A |
| 13 | 0.05 | 0.67 | 0.33 | 15 | A | A | A | A | A |
| 14 | 0.05 | 0.67 | 0.33 | 20 | A | A | B | B | B |
| 15 | 0.05 | 0.67 | 0.33 | 30 | A | A | B | B | B |
| 16 | 0.05 | 0.67 | 0.33 | 40 | A | A | C | C | C |
| 17 | 0.05 | 0.75 | 0.25 | — | C | C | — | — | C |
| 18 | 0.05 | 0.75 | 0.25 | 3 | B | B | A | A | B |
| 19 | 0.05 | 0.75 | 0.25 | 5 | A | A | A | A | A |
| 20 | 0.05 | 0.75 | 0.25 | 10 | A | A | A | A | A |
| 21 | 0.05 | 0.75 | 0.25 | 15 | A | A | A | A | A |
| 22 | 0.05 | 0.75 | 0.25 | 20 | A | A | B | B | B |
| 23 | 0.05 | 0.75 | 0.25 | 30 | A | A | B | B | B |
| 24 | 0.05 | 0.75 | 0.25 | 40 | A | A | C | C | C |

TABLE 4

| | Compositional ratio (atomic ratio) | | | Si film | Characteristics | | | | |
|---|---|---|---|---|---|---|---|---|---|
| | of oxide semiconductor | | | Thickness | Diffu- | | | Similarity to | Evalu- |
| No. | Ga/(Zn + Sn + Ga) | Zn/(Zn + Sn) | Sn/(Zn + Sn) | (nm) | sion | Adhesion | Undercut | insulator | ation |
| 25 | 0.1 | 0.5 | 0.5 | — | C | C | — | — | C |
| 26 | 0.1 | 0.5 | 0.5 | 3 | B | B | A | A | B |
| 27 | 0.1 | 0.5 | 0.5 | 5 | A | A | A | A | A |
| 28 | 0.1 | 0.5 | 0.5 | 10 | A | A | A | A | A |
| 29 | 0.1 | 0.5 | 0.5 | 15 | A | A | A | A | A |
| 30 | 0.1 | 0.5 | 0.5 | 20 | A | A | B | B | B |
| 31 | 0.1 | 0.5 | 0.5 | 30 | A | A | B | B | B |
| 32 | 0.1 | 0.5 | 0.5 | 40 | A | A | C | C | C |
| 33 | 0.1 | 0.67 | 0.33 | — | C | C | — | — | C |
| 34 | 0.1 | 0.67 | 0.33 | 3 | B | B | A | A | B |
| 35 | 0.1 | 0.67 | 0.33 | 5 | A | A | A | A | A |
| 36 | 0.1 | 0.67 | 0.33 | 10 | A | A | A | A | A |
| 37 | 0.1 | 0.67 | 0.33 | 15 | A | A | A | A | A |
| 38 | 0.1 | 0.67 | 0.33 | 20 | A | A | B | B | B |
| 39 | 0.1 | 0.67 | 0.33 | 30 | A | A | B | B | B |
| 40 | 0.1 | 0.67 | 0.33 | 40 | A | A | C | C | C |
| 41 | 0.1 | 0.75 | 0.25 | — | C | C | — | — | C |
| 42 | 0.1 | 0.75 | 0.25 | 3 | B | B | A | A | B |
| 43 | 0.1 | 0.75 | 0.25 | 5 | A | A | A | A | A |
| 44 | 0.1 | 0.75 | 0.25 | 10 | A | A | A | A | A |
| 45 | 0.1 | 0.75 | 0.25 | 15 | A | A | A | A | A |
| 46 | 0.1 | 0.75 | 0.25 | 20 | A | A | B | B | B |
| 47 | 0.1 | 0.75 | 0.25 | 30 | A | A | B | B | B |
| 48 | 0.1 | 0.75 | 0.25 | 40 | A | A | C | C | C |

TABLE 5

| | Compositional ratio (atomic ratio) | | | Si film | Characteristics | | | | |
|---|---|---|---|---|---|---|---|---|---|
| | of oxide semiconductor | | | Thickness | Diffu- | | | Similarity to | Evalu- |
| No. | Ga/(Zn + Sn + Ga) | Zn/(Zn + Sn) | Sn/(Zn + Sn) | (nm) | sion | Adhesion | Undercut | insulator | ation |
| 49 | 0.2 | 0.5 | 0.5 | — | C | C | — | — | C |
| 50 | 0.2 | 0.5 | 0.5 | 3 | B | B | A | A | B |
| 51 | 0.2 | 0.5 | 0.5 | 5 | A | A | A | A | A |
| 52 | 0.2 | 0.5 | 0.5 | 10 | A | A | A | A | A |
| 53 | 0.2 | 0.5 | 0.5 | 15 | A | A | A | A | A |
| 54 | 0.2 | 0.5 | 0.5 | 20 | A | A | B | B | B |
| 55 | 0.2 | 0.5 | 0.5 | 30 | A | A | B | B | B |
| 56 | 0.2 | 0.5 | 0.5 | 40 | A | A | C | C | C |
| 57 | 0.2 | 0.67 | 0.33 | — | C | C | — | — | C |
| 58 | 0.2 | 0.67 | 0.33 | 3 | B | B | A | A | B |
| 59 | 0.2 | 0.67 | 0.33 | 5 | A | A | A | A | A |
| 60 | 0.2 | 0.67 | 0.33 | 10 | A | A | A | A | A |
| 61 | 0.2 | 0.67 | 0.33 | 15 | A | A | A | A | A |
| 62 | 0.2 | 0.67 | 0.33 | 20 | A | A | B | B | B |
| 63 | 0.2 | 0.67 | 0.33 | 30 | A | A | B | B | B |
| 64 | 0.2 | 0.67 | 0.33 | 40 | A | A | C | C | C |
| 65 | 0.2 | 0.75 | 0.25 | — | C | C | — | — | C |
| 66 | 0.2 | 0.75 | 0.25 | 3 | B | B | A | A | B |
| 67 | 0.2 | 0.75 | 0.25 | 5 | A | A | A | A | A |
| 68 | 0.2 | 0.75 | 0.25 | 10 | A | A | A | A | A |
| 69 | 0.2 | 0.75 | 0.25 | 15 | A | A | A | A | A |
| 70 | 0.2 | 0.75 | 0.25 | 20 | A | A | B | B | B |
| 71 | 0.2 | 0.75 | 0.25 | 30 | A | A | B | B | B |
| 72 | 0.2 | 0.75 | 0.25 | 40 | A | A | C | C | C |

TABLE 6

| | Compositional ratio (atomic ratio) | | | Si film | Characteristics | | | | |
|---|---|---|---|---|---|---|---|---|---|
| | of oxide semiconductor | | | Thickness | Diffu- | | | Similarity to | Evalu- |
| No. | In/(Zn + Sn + Ga) | Zn/(Zn + Sn) | Sn/(Zn + Sn) | (nm) | sion | Adhesion | Undercut | insulator | ation |
| 1 | 0.05 | 0.5 | 0.5 | — | C | C | — | — | C |
| 2 | 0.05 | 0.5 | 0.5 | 3 | B | B | A | A | B |
| 3 | 0.05 | 0.5 | 0.5 | 5 | A | A | A | A | A |
| 4 | 0.05 | 0.5 | 0.5 | 10 | A | A | A | A | A |
| 5 | 0.05 | 0.5 | 0.5 | 15 | A | A | A | A | A |
| 6 | 0.05 | 0.5 | 0.5 | 20 | A | A | B | B | B |
| 7 | 0.05 | 0.5 | 0.5 | 30 | A | A | B | B | B |
| 8 | 0.05 | 0.5 | 0.5 | 40 | A | A | C | C | C |
| 9 | 0.05 | 0.67 | 0.33 | — | C | C | — | — | C |
| 10 | 0.05 | 0.67 | 0.33 | 3 | B | B | A | A | B |
| 11 | 0.05 | 0.67 | 0.33 | 5 | A | A | A | A | A |
| 12 | 0.05 | 0.67 | 0.33 | 10 | A | A | A | A | A |
| 13 | 0.05 | 0.67 | 0.33 | 15 | A | A | A | A | A |
| 14 | 0.05 | 0.67 | 0.33 | 20 | A | A | B | B | B |
| 15 | 0.05 | 0.67 | 0.33 | 30 | A | A | B | B | B |
| 16 | 0.05 | 0.67 | 0.33 | 40 | A | A | C | C | C |
| 17 | 0.05 | 0.75 | 0.25 | — | C | C | — | — | C |
| 18 | 0.05 | 0.75 | 0.25 | 3 | B | B | A | A | B |
| 19 | 0.05 | 0.75 | 0.25 | 5 | A | A | A | A | A |
| 20 | 0.05 | 0.75 | 0.25 | 10 | A | A | A | A | A |
| 21 | 0.05 | 0.75 | 0.25 | 15 | A | A | A | A | A |
| 22 | 0.05 | 0.75 | 0.25 | 20 | A | A | B | B | B |
| 23 | 0.05 | 0.75 | 0.25 | 30 | A | A | B | B | B |
| 24 | 0.05 | 0.75 | 0.25 | 40 | A | A | C | C | C |

TABLE 7

| | Compositional ratio (atomic ratio) | | | Si film | Characteristics | | | | |
|---|---|---|---|---|---|---|---|---|---|
| | of oxide semiconductor | | | Thickness | Diffu- | | | Similarity to | Evalu- |
| No. | In/(Zn + Sn + Ga) | Zn/(Zn + Sn) | Sn/(Zn + Sn) | (nm) | sion | Adhesion | Undercut | insulator | ation |
| 25 | 0.1 | 0.5 | 0.5 | — | C | C | — | — | C |
| 26 | 0.1 | 0.5 | 0.5 | 3 | B | B | A | A | B |
| 27 | 0.1 | 0.5 | 0.5 | 5 | A | A | A | A | A |
| 28 | 0.1 | 0.5 | 0.5 | 10 | A | A | A | A | A |
| 29 | 0.1 | 0.5 | 0.5 | 15 | A | A | A | A | A |
| 30 | 0.1 | 0.5 | 0.5 | 20 | A | A | B | B | B |
| 31 | 0.1 | 0.5 | 0.5 | 30 | A | A | B | B | B |
| 32 | 0.1 | 0.5 | 0.5 | 40 | A | A | C | C | C |
| 33 | 0.1 | 0.67 | 0.33 | — | C | C | — | — | C |
| 34 | 0.1 | 0.67 | 0.33 | 3 | B | B | A | A | B |
| 35 | 0.1 | 0.67 | 0.33 | 5 | A | A | A | A | A |
| 36 | 0.1 | 0.67 | 0.33 | 10 | A | A | A | A | A |
| 37 | 0.1 | 0.67 | 0.33 | 15 | A | A | A | A | A |
| 38 | 0.1 | 0.67 | 0.33 | 20 | A | A | B | B | B |
| 39 | 0.1 | 0.67 | 0.33 | 30 | A | A | B | B | B |
| 40 | 0.1 | 0.67 | 0.33 | 40 | A | A | C | C | C |
| 41 | 0.1 | 0.75 | 0.25 | — | C | C | — | — | C |
| 42 | 0.1 | 0.75 | 0.25 | 3 | B | B | A | A | B |
| 43 | 0.1 | 0.75 | 0.25 | 5 | A | A | A | A | A |
| 44 | 0.1 | 0.75 | 0.25 | 10 | A | A | A | A | A |
| 45 | 0.1 | 0.75 | 0.25 | 15 | A | A | A | A | A |
| 46 | 0.1 | 0.75 | 0.25 | 20 | A | A | B | B | B |
| 47 | 0.1 | 0.75 | 0.25 | 30 | A | A | B | B | B |
| 48 | 0.1 | 0.75 | 0.25 | 40 | A | A | C | C | C |

TABLE 8

| | Compositional ratio (atomic ratio) | | | Si film | Characteristics | | | | |
|---|---|---|---|---|---|---|---|---|---|
| | of oxide semiconductor | | | Thickness | Diffu- | | | Similarity to | Evalu- |
| No. | In/(Zn + Sn + Ga) | Zn/(Zn + Sn) | Sn/(Zn + Sn) | (nm) | sion | Adhesion | Undercut | insulator | ation |
| 49 | 0.2 | 0.5 | 0.5 | — | C | C | — | — | C |
| 50 | 0.2 | 0.5 | 0.5 | 3 | B | B | A | A | B |
| 51 | 0.2 | 0.5 | 0.5 | 5 | A | A | A | A | A |
| 52 | 0.2 | 0.5 | 0.5 | 10 | A | A | A | A | A |
| 53 | 0.2 | 0.5 | 0.5 | 15 | A | A | A | A | A |
| 54 | 0.2 | 0.5 | 0.5 | 20 | A | A | B | B | B |
| 55 | 0.2 | 0.5 | 0.5 | 30 | A | A | B | B | B |
| 56 | 0.2 | 0.5 | 0.5 | 40 | A | A | C | C | C |
| 57 | 0.2 | 0.67 | 0.33 | — | C | C | — | — | C |
| 58 | 0.2 | 0.67 | 0.33 | 3 | B | B | A | A | B |
| 59 | 0.2 | 0.67 | 0.33 | 5 | A | A | A | A | A |
| 60 | 0.2 | 0.67 | 0.33 | 10 | A | A | A | A | A |
| 61 | 0.2 | 0.67 | 0.33 | 15 | A | A | A | A | A |
| 62 | 0.2 | 0.67 | 0.33 | 20 | A | A | B | B | B |
| 63 | 0.2 | 0.67 | 0.33 | 30 | A | A | B | B | B |
| 64 | 0.2 | 0.67 | 0.33 | 40 | A | A | C | C | C |
| 65 | 0.2 | 0.75 | 0.25 | — | C | C | — | — | C |
| 66 | 0.2 | 0.75 | 0.25 | 3 | B | B | A | A | B |
| 67 | 0.2 | 0.75 | 0.25 | 5 | A | A | A | A | A |
| 68 | 0.2 | 0.75 | 0.25 | 10 | A | A | A | A | A |
| 69 | 0.2 | 0.75 | 0.25 | 15 | A | A | A | A | A |
| 70 | 0.2 | 0.75 | 0.25 | 20 | A | A | B | B | B |
| 71 | 0.2 | 0.75 | 0.25 | 30 | A | A | B | B | B |
| 72 | 0.2 | 0.75 | 0.25 | 40 | A | A | C | C | C |

Tables 1 to 8 show results for various oxide semiconductors having different compositions, where Table 1 shows results for IGZO, Table 2 shows results for ZTO, Tables 3 to 5 show results for GZTO, and Tables 6 to 8 show results for IZTO. In Table 1, the proportion of each of In, Ga, and Zn in the column of “Compositional ratio of IGZO” refers to a compositional ratio (in atomic percent) among In, Ga, and Zn being compositional elements of IGZO.

In each Table, “-” as thickness of the Si film (for example, No. 1 in Table 1) refers to a case where a barrier layer includes only a pure Ti film 50 nm in thickness and includes no Si film, i.e., a case corresponding to a traditional case.

As shown in the Tables, if any of the oxide semiconductors having the different compositions was used, and if the stacked film of the Ti film and the Si film as specified in the invention was used as the barrier layer, any compositional element of the oxide semiconductor layer was prevented from diffusing into the Cu film (evaluation of diffusion: A or B), and good adhesion between the barrier layer and the oxide semiconductor was shown (evaluation of adhesion: A or B). As a result, no separation of the metal films including the barrier layer (pure Cu/pure Ti/Si) occurred. In contrast, in the case where only the pure Ti film was used, diffusion of a compositional element of the oxide semiconductor layer was failed to be prevented (evaluation of diffusion: C), and adhesion was bad (evaluation of adhesion: C).

In addition, in the case where the thickness of the Si film satisfied the preferred range specified in the invention (3 to 30 nm), the undercut length of the Si film was short, i.e., excellent dry etching performance was shown (evaluation of undercut: A or B), and excellent TFT characteristics were shown (evaluation of similarity to insulator: A or B).

In contrast, in the case where the thickness of the Si film was more than the preferred range specified in the invention, the Si film on the channel section was not sufficiently oxidized despite no problem in diffusion and adhesion, and thus excellent TFT characteristics were not shown (evaluation of similarity to insulator: C). Moreover, undercut length of the dry-etched Si film was long, i.e., dry etching performance was inferior.

In the case where the thickness of the Si film was lower than the preferred range specified in the invention, the effect of formation of the Si film was not exhibited, resulting in much diffusion, bad adhesion, and inferior TFT characteristics (not shown in Tables).

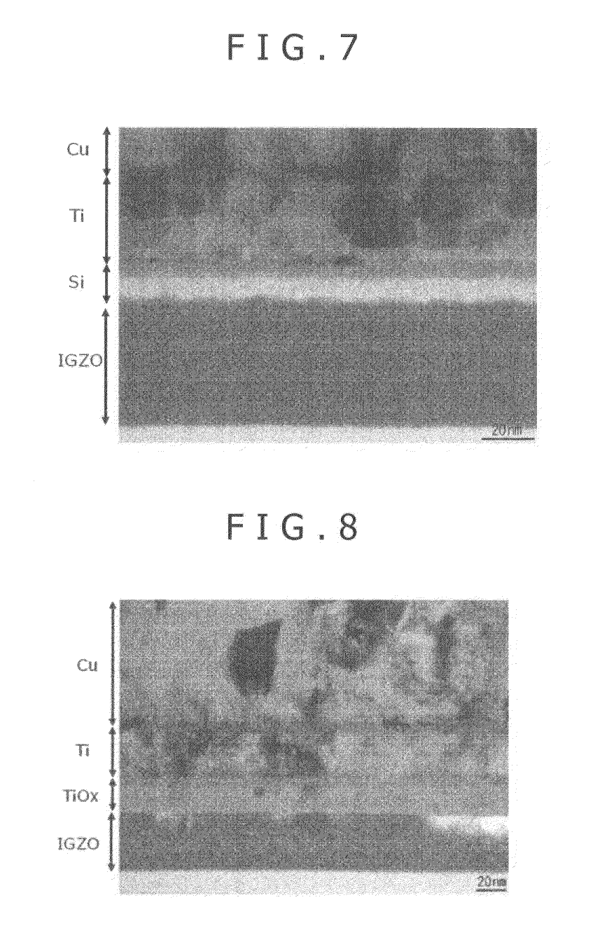

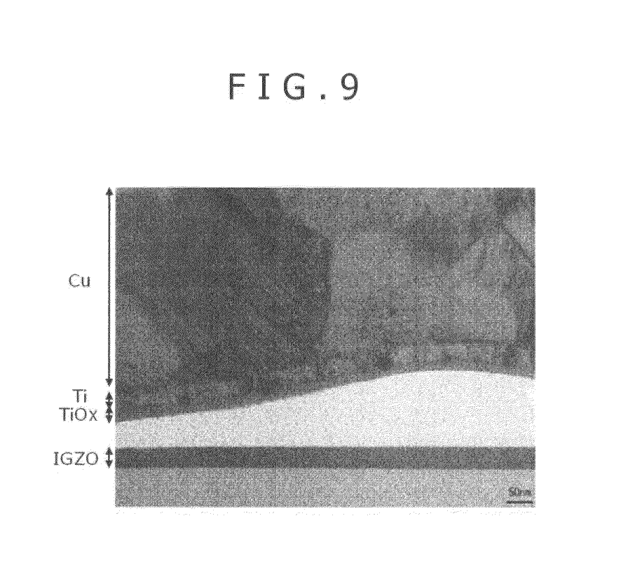

For reference, FIG. 7 shows a cross-sectional TEM image (at a magnification of 1,500,000) of No. 12 (a case of the invention) in Table 1, and FIGS. 8 and 9 show cross-sectional TEM images (at magnifications of 900,000 and 300,000) of No. 9 (a case of a traditional Cu/Ti barrier layer) in Table 1. As shown in FIG. 7, in the case where the Si film used in the invention was provided on the oxide semiconductor thin film, that Si film was in good adhesion to the oxide semiconductor thin film (in this case, IGZO). In contrast, as shown in FIG. 8, in the traditional case where only the pure Ti film was used as the barrier layer without providing the Si film, an oxidation-reduction reaction occurred at an interface between the oxide semiconductor thin film and the pure Ti film. In addition, as shown in FIG. 9, the pure Ti film was separated from IGZO at some places.

Although the above description has discussed the results with the pure Cu film used as the metal interconnection film, it has been experimentally confirmed that similar results as in the above are also obtained in other embodiments each exclusively using pure Al, Cu alloy, or Al alloy.

Moreover, although the above description has discussed the results with the pure Ti film used as the high-melting-point metal thin film, this is not limitative. It has been experimentally confirmed that the same results as in the above are also obtained with Ti alloy.

### Example 2

In Example 2, dry etching performance was evaluated based on undercut length of a dry-etched Si thin film, and TFT characteristics after the Si film was made nonconductive were examined as in the Example 1 except that a pure Mo film was used as the high-melting-point metal thin film. In the case where the pure Mo film was used as the high-melting-point metal thin film, the problems associated with use of the pure Ti film (bad adhesion between the oxide semiconductor and the Si thin film, and diffusion of a compositional element of the oxide semiconductor into the metal interconnection film) did not occur, and therefore such adhesion and diffusion were not evaluated in the Example 2.

Tables 9 to 16 collectively show the results.

TABLE 9

| | Compositional | | | Si film | Characteristics | | |
|---|---|---|---|---|---|---|---|
| | ratio of IGZO | | | Thickness | | Similarity to | Evalu- |
| No. | In | Ga | Zn | (nm) | Undercut | insulator | ation |
| 1 | 1 | 1 | 1 | — | — | — | C |
| 2 | 1 | 1 | 1 | 3 | A | A | A |
| 3 | 1 | 1 | 1 | 5 | A | A | A |
| 4 | 1 | 1 | 1 | 10 | A | A | A |
| 5 | 1 | 1 | 1 | 15 | A | A | A |
| 6 | 1 | 1 | 1 | 20 | B | B | B |
| 7 | 1 | 1 | 1 | 30 | B | B | B |
| 8 | 1 | 1 | 1 | 40 | C | C | C |
| 9 | 2 | 2 | 1 | — | — | — | C |
| 10 | 2 | 2 | 1 | 3 | A | A | A |
| 11 | 2 | 2 | 1 | 5 | A | A | A |
| 12 | 2 | 2 | 1 | 10 | A | A | A |
| 13 | 2 | 2 | 1 | 15 | A | A | A |
| 14 | 2 | 2 | 1 | 20 | B | B | B |
| 15 | 2 | 2 | 1 | 30 | B | B | B |
| 16 | 2 | 2 | 1 | 40 | C | C | C |

TABLE 10

| | Compositional ratio | | | Characteristics | | |
|---|---|---|---|---|---|---|
| | (atomic ratio) of ZTO | | Si film | | Similar- | |
| | Zn/ | Sn/ | Thickness | Under- | ity to | Evalu- |
| No. | (Zn + Sn) | (Zn + Sn) | (nm) | cut | insulator | ation |
| 1 | 0.5 | 0.5 | — | — | — | C |
| 2 | 0.5 | 0.5 | 3 | A | A | A |
| 3 | 0.5 | 0.5 | 5 | A | A | A |
| 4 | 0.5 | 0.5 | 10 | A | A | A |
| 5 | 0.5 | 0.5 | 15 | A | A | A |
| 6 | 0.5 | 0.5 | 20 | B | B | B |
| 7 | 0.5 | 0.5 | 30 | B | B | B |
| 8 | 0.5 | 0.5 | 40 | C | C | C |
| 9 | 0.67 | 0.33 | — | — | — | C |
| 10 | 0.67 | 0.33 | 3 | A | A | A |
| 11 | 0.67 | 0.33 | 5 | A | A | A |
| 12 | 0.67 | 0.33 | 10 | A | A | A |
| 13 | 0.67 | 0.33 | 15 | A | A | A |
| 14 | 0.67 | 0.33 | 20 | B | B | B |
| 15 | 0.67 | 0.33 | 30 | B | B | B |
| 16 | 0.67 | 0.33 | 40 | C | C | C |
| 17 | 0.75 | 0.25 | — | — | — | C |
| 18 | 0.75 | 0.25 | 3 | A | A | A |
| 19 | 0.75 | 0.25 | 5 | A | A | A |
| 20 | 0.75 | 0.25 | 10 | A | A | A |
| 21 | 0.75 | 0.25 | 15 | A | A | A |
| 22 | 0.75 | 0.25 | 20 | B | B | B |
| 23 | 0.75 | 0.25 | 30 | B | B | B |
| 24 | 0.75 | 0.25 | 40 | C | C | C |

TABLE 11

| | Compositional ratio (atomic ratio) | | | Si film | Characteristics | | |
|---|---|---|---|---|---|---|---|
| | of oxide semiconductor | | | Thickness | | Similarity to | Evalu- |
| No. | Ga/(Zn + Sn + Ga) | Zn/(Zn + Sn) | Sn/(Zn + Sn) | (nm) | Undercut | insulator | ation |
| 1 | 0.05 | 0.5 | 0.5 | — | — | — | C |
| 2 | 0.05 | 0.5 | 0.5 | 3 | A | A | A |
| 3 | 0.05 | 0.5 | 0.5 | 5 | A | A | A |
| 4 | 0.05 | 0.5 | 0.5 | 10 | A | A | A |
| 5 | 0.05 | 0.5 | 0.5 | 15 | A | A | A |
| 6 | 0.05 | 0.5 | 0.5 | 20 | B | B | B |
| 7 | 0.05 | 0.5 | 0.5 | 30 | B | B | B |
| 8 | 0.05 | 0.5 | 0.5 | 40 | C | C | C |
| 9 | 0.05 | 0.67 | 0.33 | — | — | — | C |
| 10 | 0.05 | 0.67 | 0.33 | 3 | A | A | A |
| 11 | 0.05 | 0.67 | 0.33 | 5 | A | A | A |
| 12 | 0.05 | 0.67 | 0.33 | 10 | A | A | A |
| 13 | 0.05 | 0.67 | 0.33 | 15 | A | A | A |
| 14 | 0.05 | 0.67 | 0.33 | 20 | B | B | B |
| 15 | 0.05 | 0.67 | 0.33 | 30 | B | B | B |
| 16 | 0.05 | 0.67 | 0.33 | 40 | C | C | C |
| 17 | 0.05 | 0.75 | 0.25 | — | — | — | C |
| 18 | 0.05 | 0.75 | 0.25 | 3 | A | A | A |
| 19 | 0.05 | 0.75 | 0.25 | 5 | A | A | A |
| 20 | 0.05 | 0.75 | 0.25 | 10 | A | A | A |
| 21 | 0.05 | 0.75 | 0.25 | 15 | A | A | A |
| 22 | 0.05 | 0.75 | 0.25 | 20 | B | B | B |
| 23 | 0.05 | 0.75 | 0.25 | 30 | B | B | B |
| 24 | 0.05 | 0.75 | 0.25 | 40 | C | C | C |

TABLE 12

| | Compositional ratio (atomic ratio) | | | Si film | Characteristics | | |
|---|---|---|---|---|---|---|---|
| | of oxide semiconductor | | | Thickness | | Similarity to | Evalu- |
| No. | Ga/(Zn + Sn + Ga) | Zn/(Zn + Sn) | Sn/(Zn + Sn) | (nm) | Undercut | insulator | ation |
| 25 | 0.1 | 0.5 | 0.5 | — | — | — | C |
| 26 | 0.1 | 0.5 | 0.5 | 3 | A | A | A |
| 27 | 0.1 | 0.5 | 0.5 | 5 | A | A | A |
| 28 | 0.1 | 0.5 | 0.5 | 10 | A | A | A |
| 29 | 0.1 | 0.5 | 0.5 | 15 | A | A | A |
| 30 | 0.1 | 0.5 | 0.5 | 20 | B | B | B |
| 31 | 0.1 | 0.5 | 0.5 | 30 | B | B | B |
| 32 | 0.1 | 0.5 | 0.5 | 40 | C | C | C |
| 33 | 0.1 | 0.67 | 0.33 | — | — | — | C |
| 34 | 0.1 | 0.67 | 0.33 | 3 | A | A | A |
| 35 | 0.1 | 0.67 | 0.33 | 5 | A | A | A |
| 36 | 0.1 | 0.67 | 0.33 | 10 | A | A | A |
| 37 | 0.1 | 0.67 | 0.33 | 15 | A | A | A |
| 38 | 0.1 | 0.67 | 0.33 | 20 | B | B | B |
| 39 | 0.1 | 0.67 | 0.33 | 30 | B | B | B |
| 40 | 0.1 | 0.67 | 0.33 | 40 | C | C | C |
| 41 | 0.1 | 0.75 | 0.25 | — | — | — | C |
| 42 | 0.1 | 0.75 | 0.25 | 3 | A | A | A |
| 43 | 0.1 | 0.75 | 0.25 | 5 | A | A | A |
| 44 | 0.1 | 0.75 | 0.25 | 10 | A | A | A |
| 45 | 0.1 | 0.75 | 0.25 | 15 | A | A | A |
| 46 | 0.1 | 0.75 | 0.25 | 20 | B | B | B |
| 47 | 0.1 | 0.75 | 0.25 | 30 | B | B | B |
| 48 | 0.1 | 0.75 | 0.25 | 40 | C | C | C |

TABLE 13

| | Compositional ratio (atomic ratio) | | | Si film | Characteristics | | |
|---|---|---|---|---|---|---|---|
| | of oxide semiconductor | | | Thickness | | Similarity to | Evalu- |
| No. | Ga/(Zn + Sn + Ga) | Zn/(Zn + Sn) | Sn/(Zn + Sn) | (nm) | Undercut | insulator | ation |
| 49 | 0.2 | 0.5 | 0.5 | — | — | — | C |
| 50 | 0.2 | 0.5 | 0.5 | 3 | A | A | A |
| 51 | 0.2 | 0.5 | 0.5 | 5 | A | A | A |
| 52 | 0.2 | 0.5 | 0.5 | 10 | A | A | A |
| 53 | 0.2 | 0.5 | 0.5 | 15 | A | A | A |
| 54 | 0.2 | 0.5 | 0.5 | 20 | B | B | B |
| 55 | 0.2 | 0.5 | 0.5 | 30 | B | B | B |
| 56 | 0.2 | 0.5 | 0.5 | 40 | C | C | C |
| 57 | 0.2 | 0.67 | 0.33 | — | — | — | C |
| 58 | 0.2 | 0.67 | 0.33 | 3 | A | A | A |
| 59 | 0.2 | 0.67 | 0.33 | 5 | A | A | A |
| 60 | 0.2 | 0.67 | 0.33 | 10 | A | A | A |
| 61 | 0.2 | 0.67 | 0.33 | 15 | A | A | A |
| 62 | 0.2 | 0.67 | 0.33 | 20 | B | B | B |
| 63 | 0.2 | 0.67 | 0.33 | 30 | B | B | B |
| 64 | 0.2 | 0.67 | 0.33 | 40 | C | C | C |
| 65 | 0.2 | 0.75 | 0.25 | — | — | — | C |
| 66 | 0.2 | 0.75 | 0.25 | 3 | A | A | A |
| 67 | 0.2 | 0.75 | 0.25 | 5 | A | A | A |
| 68 | 0.2 | 0.75 | 0.25 | 10 | A | A | A |
| 69 | 0.2 | 0.75 | 0.25 | 15 | A | A | A |
| 70 | 0.2 | 0.75 | 0.25 | 20 | B | B | B |
| 71 | 0.2 | 0.75 | 0.25 | 30 | B | B | B |
| 72 | 0.2 | 0.75 | 0.25 | 40 | C | C | C |

TABLE 14

| | Compositional ratio (atomic ratio) | | | Si film | Characteristics | | |
|---|---|---|---|---|---|---|---|
| | of oxide semiconductor | | | Thickness | | Similarity to | Evalu- |
| No. | In/(Zn + Sn + Ga) | Zn/(Zn + Sn) | Sn/(Zn + Sn) | (nm) | Undercut | insulator | ation |
| 1 | 0.05 | 0.5 | 0.5 | — | — | — | C |
| 2 | 0.05 | 0.5 | 0.5 | 3 | A | A | A |
| 3 | 0.05 | 0.5 | 0.5 | 5 | A | A | A |
| 4 | 0.05 | 0.5 | 0.5 | 10 | A | A | A |
| 5 | 0.05 | 0.5 | 0.5 | 15 | A | A | A |
| 6 | 0.05 | 0.5 | 0.5 | 20 | B | B | B |
| 7 | 0.05 | 0.5 | 0.5 | 30 | B | B | B |
| 8 | 0.05 | 0.5 | 0.5 | 40 | C | C | C |
| 9 | 0.05 | 0.67 | 0.33 | — | — | — | C |
| 10 | 0.05 | 0.67 | 0.33 | 3 | A | A | A |
| 11 | 0.05 | 0.67 | 0.33 | 5 | A | A | A |
| 12 | 0.05 | 0.67 | 0.33 | 10 | A | A | A |
| 13 | 0.05 | 0.67 | 0.33 | 15 | A | A | A |
| 14 | 0.05 | 0.67 | 0.33 | 20 | B | B | B |
| 15 | 0.05 | 0.67 | 0.33 | 30 | B | B | B |
| 16 | 0.05 | 0.67 | 0.33 | 40 | C | C | C |
| 17 | 0.05 | 0.75 | 0.25 | — | — | — | C |
| 18 | 0.05 | 0.75 | 0.25 | 3 | A | A | A |
| 19 | 0.05 | 0.75 | 0.25 | 5 | A | A | A |
| 20 | 0.05 | 0.75 | 0.25 | 10 | A | A | A |
| 21 | 0.05 | 0.75 | 0.25 | 15 | A | A | A |
| 22 | 0.05 | 0.75 | 0.25 | 20 | B | B | B |
| 23 | 0.05 | 0.75 | 0.25 | 30 | B | B | B |
| 24 | 0.05 | 0.75 | 0.25 | 40 | C | C | C |

TABLE 15

| | Compositional ratio (atomic ratio) | | | Si film | Characteristics | | |
|---|---|---|---|---|---|---|---|
| | of oxide semiconductor | | | Thickness | | Similarity to | Evalu- |
| No. | In/(Zn + Sn + Ga) | Zn/(Zn + Sn) | Sn/(Zn + Sn) | (nm) | Undercut | insulator | ation |
| 25 | 0.1 | 0.5 | 0.5 | — | — | — | C |
| 26 | 0.1 | 0.5 | 0.5 | 3 | A | A | A |
| 27 | 0.1 | 0.5 | 0.5 | 5 | A | A | A |
| 28 | 0.1 | 0.5 | 0.5 | 10 | A | A | A |
| 29 | 0.1 | 0.5 | 0.5 | 15 | A | A | A |
| 30 | 0.1 | 0.5 | 0.5 | 20 | B | B | B |
| 31 | 0.1 | 0.5 | 0.5 | 30 | B | B | B |
| 32 | 0.1 | 0.5 | 0.5 | 40 | C | C | C |
| 33 | 0.1 | 0.67 | 0.33 | — | — | — | C |
| 34 | 0.1 | 0.67 | 0.33 | 3 | A | A | A |
| 35 | 0.1 | 0.67 | 0.33 | 5 | A | A | A |
| 36 | 0.1 | 0.67 | 0.33 | 10 | A | A | A |
| 37 | 0.1 | 0.67 | 0.33 | 15 | A | A | A |
| 38 | 0.1 | 0.67 | 0.33 | 20 | B | B | B |
| 39 | 0.1 | 0.67 | 0.33 | 30 | B | B | B |
| 40 | 0.1 | 0.67 | 0.33 | 40 | C | C | C |
| 41 | 0.1 | 0.75 | 0.25 | — | — | — | C |
| 42 | 0.1 | 0.75 | 0.25 | 3 | A | A | A |
| 43 | 0.1 | 0.75 | 0.25 | 5 | A | A | A |
| 44 | 0.1 | 0.75 | 0.25 | 10 | A | A | A |
| 45 | 0.1 | 0.75 | 0.25 | 15 | A | A | A |
| 46 | 0.1 | 0.75 | 0.25 | 20 | B | B | B |
| 47 | 0.1 | 0.75 | 0.25 | 30 | B | B | B |
| 48 | 0.1 | 0.75 | 0.25 | 40 | C | C | C |

TABLE 16

| | Compositional ratio (atomic ratio) | | | Si film | Characteristics | | |
|---|---|---|---|---|---|---|---|
| | of oxide semiconductor | | | Thickness | | Similarity to | Evalu- |
| No. | In/(Zn + Sn + Ga) | Zn/(Zn + Sn) | Sn/(Zn + Sn) | (nm) | Undercut | insulator | ation |
| 49 | 0.2 | 0.5 | 0.5 | — | — | — | C |
| 50 | 0.2 | 0.5 | 0.5 | 3 | A | A | A |
| 51 | 0.2 | 0.5 | 0.5 | 5 | A | A | A |
| 52 | 0.2 | 0.5 | 0.5 | 10 | A | A | A |
| 53 | 0.2 | 0.5 | 0.5 | 15 | A | A | A |
| 54 | 0.2 | 0.5 | 0.5 | 20 | B | B | B |
| 55 | 0.2 | 0.5 | 0.5 | 30 | B | B | B |
| 56 | 0.2 | 0.5 | 0.5 | 40 | C | C | C |
| 57 | 0.2 | 0.67 | 0.33 | — | — | — | C |
| 58 | 0.2 | 0.67 | 0.33 | 3 | A | A | A |
| 59 | 0.2 | 0.67 | 0.33 | 5 | A | A | A |
| 60 | 0.2 | 0.67 | 0.33 | 10 | A | A | A |
| 61 | 0.2 | 0.67 | 0.33 | 15 | A | A | A |
| 62 | 0.2 | 0.67 | 0.33 | 20 | B | B | B |
| 63 | 0.2 | 0.67 | 0.33 | 30 | B | B | B |
| 64 | 0.2 | 0.67 | 0.33 | 40 | C | C | C |
| 65 | 0.2 | 0.75 | 0.25 | — | — | — | C |
| 66 | 0.2 | 0.75 | 0.25 | 3 | A | A | A |
| 67 | 0.2 | 0.75 | 0.25 | 5 | A | A | A |
| 68 | 0.2 | 0.75 | 0.25 | 10 | A | A | A |
| 69 | 0.2 | 0.75 | 0.25 | 15 | A | A | A |
| 70 | 0.2 | 0.75 | 0.25 | 20 | B | B | B |
| 71 | 0.2 | 0.75 | 0.25 | 30 | B | B | B |
| 72 | 0.2 | 0.75 | 0.25 | 40 | C | C | C |

Tables 9 to 16 show results for various oxide semiconductors having different compositions, where Table 9 shows results for IGZO, Table 10 shows results for ZTO, Tables 11 to 13 show results for GZTO, and Tables 14 to 16 show results for IZTO.

As shown in the Tables, if any of the oxide semiconductors having the different compositions was used, the following results were shown. That is, when the stacked film of the Mo film and the Si film as specified in the invention was used as the barrier layer, and when the thickness of the Si film satisfied the preferred range specified in the invention (3 to 30 nm), the undercut length of the Si film was short, i.e., excellent dry etching performance was shown (evaluation of undercut: A (good) or B (pretty good)), and excellent TFT characteristics were shown (evaluation of similarity to insulator: A (good) or B (pretty good)).

In contrast, in the case where the thickness of the Si film was more than the preferred range specified in the invention, the Si film on the channel section was not sufficiently oxidized, and thus excellent TFT characteristics were not shown (evaluation of similarity to insulator: C (bad)). Moreover, undercut length of the Si film increased, resulting in inferior dry etching performance.

Although the above description has discussed the results with the pure Cu film used as the metal interconnection film, it has been experimentally confirmed that similar results as in the above are also obtained in other embodiments each exclusively using pure Al, Cu alloy, or Al alloy.

Moreover, although the above description has discussed the results with the pure Mo film used as the high-melting-point metal thin film, this is not limitative. It has been experimentally confirmed that similar results as in the above are also obtained with Mo alloy, pure Ta, or Ta alloy.

Although the application has been described in detail with reference to particular embodiments, it should be understood by those skilled in the art that various alterations and modifications thereof may be made without departing from the spirit and the scope of the invention.

The present application is based on Japanese patent application (JP-2010-254180) filed on Nov. 12, 2010, the content of which is hereby incorporated by reference.

### INDUSTRIAL APPLICABILITY

According to the present invention, an interconnection structure having an oxide semiconductor layer includes a Si thin film, which is interposed between a traditional high-melting-point-metal barrier metal layer (high-melting-point-metal thin film) and the oxide semiconductor thin film, as a barrier layer that suppresses an oxidation-reduction reaction of a metal as an interconnection material with the oxide semiconductor thin film while effectively preventing diffusion of the metal into the oxide semiconductor, which results in stable TFT characteristics, and consequently a display having improved quality can be provided.

Moreover, according to the invention, the Si thin film serves as an etch stop layer during wet etching; hence, an interconnection structure having excellent fine-processability can be provided despite providing no etch stop layer unlike in the past. In other words, the metal interconnection film and the high-melting-point-metal barrier metal layer on the Si thin film are sequentially patterned by wet etching, and then the Si thin film is dry-etched, or is made nonconductive (the entire Si film is changed into an insulator film such as a Si oxide film) by, for example, plasma oxidation, so that a display having excellent TFT characteristics can be provided even after fine processing. In this way, according to the invention, formation of the etch stop layer can be omitted, and thus the number of masks can be decreased in a TFT manufacturing process, and consequently a display, which is inexpensive and high in production efficiency, can be provided.

### DESCRIPTION OF THE REFERENCE NUMERALS AND SIGNS

1 substrate
2 gate electrode
3 gate insulator film
4 oxide semiconductor layer
5 source/drain electrodes, drain electrode
6 protective film
7 contact hole
8 transparent conductive film
9 Ti thin film (high-melting-point metal thin film)
10 Si thin film
11 Si oxide film
12 etch stop layer

1. An interconnection structure, comprising:
a substrate;
a semiconductor layer for a thin film transistor on the substrate;
a metal interconnection film on the semiconductor layer; and
a barrier layer between the semiconductor layer and the metal interconnection film,
wherein the semiconductor layer comprises oxide semiconductor, and
the barrier layer has a stacked structure of a high-melting-point-metal thin film and a Si thin film, in which the Si thin film is directly connected to the semiconductor layer.

2. The interconnection structure according to claim 1, wherein the high-melting-point-metal thin film is configured of one selected from the group consisting of a pure Ti thin film, a Ti alloy thin film, a pure Mo thin film, and a Mo alloy thin film.

3. The interconnection structure according to claim 1, wherein the Si thin film has a thickness of from 3 to 30 nm.

4. The interconnection structure according to claim 1, wherein the metal interconnection film is configured of one selected from the group consisting of a pure Al film, an Al alloy film comprising at least 90 at % Al, a pure Cu film, and a Cu alloy film comprising at least 90 at % Cu.

5. The interconnection structure according to claim 1, wherein the oxide semiconductor is composed of an oxide comprising at least one element selected from the group consisting of In, Ga, Zn, and Sn.

6. A display, comprising:
the interconnection structure according to claim 1.

7. A display, comprising:
the interconnection structure according to claim 2.

8. A display, comprising:
the interconnection structure according to claim 3.

9. A display, comprising:
the interconnection structure according to claim 4.

10. A display, comprising:
the interconnection structure according to claim 5.
